(19) United States
(12) Patent Application Publication
(10) Pub. No.: US 2008/0093664 A1
(43) Pub. Date: Apr. 24, 2008

(54) Memory device and method of manufacturing the same

(75) Inventors: Eun-Jung Yun, Seoul (KR); Min-Sang Kim, Seoul (KR); Sung-Min Kim, Incheon (KR); Dong-Won Kim, Seongnam-si (KR); Sung-Hwan Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/894,449

(22) Filed: Aug. 21, 2007

(30) Foreign Application Priority Data
Aug. 22, 2006 (KR) 10-2006-0079407

(51) Int. Cl. H01L 29/792; H01L 21/336

(52) U.S. Cl. 257/324; 438/287; 257/E29.309; 257/E21.423

(57) ABSTRACT

In a memory device and a method of manufacturing the memory device, the memory device includes a first gate electrode enclosed by a first gate insulating layer, a second gate electrode enclosed by a second gate insulating layer that can be an ONO layer, and a channel region vertically extending between the first gate electrode and the second gate electrode. The first gate electrode is used for removing a charge trapped in the second gate insulating layer. Thus, the memory device can have an improved characteristic when performing an erase operation.

### CROSS-REFERENCE TO RELATED APPLICATION

This application claims priority under 35 U.S.C. § 119 to Korean Patent Application No. 10-2006-0079407 filed on Aug. 22, 2006 in the Korean Intellectual Property Office, the contents of which is incorporated herein by reference in its entirety.

### BACKGROUND OF THE INVENTION

1. Field of the Invention

The present invention relates to a memory device and a method of manufacturing the memory device. More particularly, the present invention relates to a memory device for storing a data and a method of manufacturing the memory device.

2. Description of the Related Art

In general, semiconductor memory devices are classified as either volatile memory devices or non-volatile memory devices. Examples of volatile memory devices include dynamic random access memory (DRAM) devices and static random access memory (SRAM) devices. The data input speed and data output speed of the volatile memory device are relatively fast. However, data stored in the non-volatile memory device are not retained when power is removed.

An example of a non-volatile memory device is a read-only memory (ROM) device, such as an electrically erasable programmable read-only memory (EEPROM) device. Recently, flash memory devices, i.e., a type of EEPROM device, have enjoyed widespread use. Data input speed and data output speed of a flash memory device are relatively slow. However, a flash memory device can retain its data even when power is removed. In order to program and/or erase data, the flash memory device can employ Fowler-Nordheim tunneling or hot electron injection. In addition, flash memory devices are generally classified as either floating gate type flash memory devices or silicon-oxide-nitride-oxide-semiconductor (SONOS) type flash memory devices.

Recently, a method for improving integrity of a semiconductor device has been widely researched. As an example, a non-volatile memory device having a single control gate and two floating gates is disclosed in U.S. Pat. No. 5,834,808 issued to Tsukiji. In another example, a 2-bit non-volatile semiconductor memory cell including two diffusion regions formed at a substrate, a channel region formed between the diffusion regions, and an oxide-nitride-oxide (ONO) layer is disclosed in U.S. Pat. No. 6,649,972 issued to Eitan. In accordance with U.S. Pat. No. 6,649,972, the ONO layer includes a first oxide layer, a nitride layer, and a second oxide layer. The nitride layer has a thickness below about 100 Å and has two charge storing regions.

However, the integrity of the semiconductor device still needs to be improved in spite of advances in the field shown in the previously filed inventions of the above patents. Particularly, in the above patents, storage density of data in the non-volatile memory device is improved by varying a structure of the nitride or using the nitride layer as a data storing layer. However, the floating gate and the nitride layer are horizontally formed. Thus, it is difficult to reduce a size of the non-volatile memory device efficiently.

### SUMMARY OF THE INVENTION

An example embodiment of the present invention provides a memory device having a vertically extending channel region and having a superior erase operation characteristic.

An example embodiment of the present invention provides a method of manufacturing the memory device.

In accordance with aspect of the present invention, there is provided a memory device including a first gate electrode having two sidewalls, a first gate insulating layer, a pair of channel regions, a pair of first source/drain regions, a pair of second source/drain regions, a second gate electrode, and a second gate insulating layer. The first gate insulating layer is provided on both sidewalls of the first gate electrode. The pair of channel regions extends horizontally along a central portion of the first gate electrode. The pair of channel regions vertically extends such that the pair of channel regions makes contact with the first gate insulating layer. The pair of first source/drain regions extends horizontally along a lower portion of the first gate electrode. The pair of first source/drain regions makes contact with the first gate insulating layer. The pair of second source/drain regions extends horizontally along an upper portion of the first gate electrode. The pair of second source/drain regions makes contact with the first gate insulating layer. The second gate electrode is located between the first source/drain region and the second source/drain region. The second gate electrode extends horizontally adjacent to the channel region. The second gate insulating layer encloses the second gate electrode. The second gate insulating layer is an ONO (silicon oxide/silicon nitride/silicon oxide) layer.

The first and second source/drain regions can include a first impurity. The channel region can include a second impurity having an opposite polarity to the first impurity.

The pair of first source/drain regions can be connected to each other beneath the first gate electrode.

The memory device can further include an insulating layer beneath the first gate electrode.

The memory device can further include a single crystalline interlayer vertically connected to the channel region. In this case, the second gate electrode can have a structure enclosing the single crystalline interlayer.

The second gate electrode can include an upper portion located on the single crystalline interlayer, a lower portion located beneath the single crystalline interlayer, and a connection portion located on a side portion of the single crystalline interlayer to connect the upper portion to the lower portion.

In accordance with another aspect of the present invention, there is provided a method of manufacturing a memory device. In the method, a first single crystalline layer, a sacrificial single crystalline layer, and a second single crystalline layer are sequentially formed at a substrate. A groove having two sidewalls from which the first single crystalline layer, the sacrificial single crystalline layer and the second single crystalline layer are exposed is formed. A single crystalline thin film having a relatively uniform thickness is formed on an inner face of the groove. A first gate insulating layer having a substantially uniform thickness is formed on the single crystalline thin film. A first gate electrode is formed on the first gate insulating layer to fill up the groove. The sacrificial single crystalline layer is removed. An ONO layer is formed on an inner face of a space formed by removing the sacrificial single crystalline layer. A second gate electrode is formed on the ONO layer such that the second gate electrode fills up the space formed by removing the sacrificial single crystalline layer.

The first and second single crystalline layers can be doped with a first impurity.

The single crystalline thin film can be doped with a second impurity having an opposite polarity to the first impurity.

A surface portion of the substrate can be used as the first single crystalline layer. The sacrificial single crystalline layer, the second single crystalline layer, and the single crystalline thin film can be formed by an epitaxial growth process.

An insulating layer can be further formed on the single crystalline thin film before the first gate insulating layer is formed. The insulating layer can extend horizontally along the first single crystalline layer.

A preliminary insulating layer can be formed on the single crystalline thin film by depositing an insulating material to fill up the groove and then etching the insulating material.

The first single crystalline layer can be exposed from a bottom face of the groove. In this case, a pair of first source/drain regions can be connected to each other.

On the other hand, the substrate can be exposed from the bottom face of the groove. In this case, a pair of first source/drain regions can be spaced apart from each other.

In accordance with yet another aspect of the present invention, there is provided a method of manufacturing a memory device. In the method, an active region is formed at a substrate. The active region can include a first single crystalline layer, a lower sacrificial single crystalline layer, a single crystalline interlayer, an upper sacrificial single crystalline layer, and a second single crystalline layer that are subsequently formed. The method includes enclosing the active region with an isolation layer. A groove is formed in the active region and the isolation layer. The groove has two sidewalls from which the first single crystalline layer, the lower sacrificial single crystalline layer, the single crystalline interlayer, the upper sacrificial single crystalline layer, and the second single crystalline layer are exposed. A single crystalline thin film is formed on an inner face of the groove. The single crystalline layer has a substantially uniform thickness. A first gate insulating layer is formed on the single crystalline thin film. The first gate insulting layer has a substantially uniform thickness. A first gate electrode is formed on the first gate insulating layer to fill up the groove. A recess is formed in the isolation layer. The recess exposes the first and second sacrificial single crystalline layers. The first and second sacrificial single crystalline layers are removed through the recess. A wet etching process is performed on the isolation layer to enlarge a space formed by removing the first and second sacrificial single crystalline layers. An ONO layer is formed on an inner face of the space. The ONO layer has a substantially uniform thickness. A second gate electrode is formed on ONO layer to fill up the space.

The first and second single crystalline layers can be doped with a first impurity.

The single crystalline thin film can be doped with a second impurity having an opposite polarity to the first impurity.

A surface portion of the substrate can be used as the first single crystalline layer. The upper sacrificial single crystalline layer, the single crystalline interlayer, the upper single crystalline layer, the second single crystalline layer, and the single crystalline thin film can be formed by an epitaxial growth process.

An insulating layer can be further formed on the single crystalline thin film before the first gate insulating layer is formed. The insulating layer can extend horizontally along the first single crystalline layer. Particularly, a preliminary insulating layer can be formed on the single crystalline thin film by depositing an insulating material to fill up the groove and then etching the insulating material.

The first single crystalline layer can be exposed from a bottom face of the groove. In this case, a pair of first source/drain regions can be connected to each other.

On the other hand, the substrate can be exposed from the bottom face of the groove. In this case, a pair of first source/drain regions can be spaced apart from each other.

According to the present invention, a second gate insulating layer is an ONO layer. Thus, a memory device can be manufactured by using a charge trap characteristic of a nitride layer included in the ONO layer. In addition, charges stored in the ONO layer can be efficiently removed by a first gate electrode, and thus an erase operation of the memory device can be improved.

### BRIEF DESCRIPTION OF THE DRAWINGS

The above and other advantages of the present invention will become readily apparent by reference to the following detailed description when considered in conjunction with the accompanying drawings, in which:

FIG. 1 is a cross-sectional view illustrating an example embodiment of a memory device in accordance with the present invention;

FIGS. 2 to 14 are cross-sectional views illustrating an embodiment of a method of manufacturing a memory device in FIG. 1;

FIG. 15 is a cross-sectional view illustrating another example embodiment of a memory device in accordance with the present invention;

FIGS. 16 to 18 are cross-sectional views illustrating an embodiment of a method of manufacturing a memory device in FIG. 15;

FIG. 19 is a cross-sectional view illustrating another example embodiment of a memory device in accordance with the present invention;

FIGS. 20 to 22 are cross-sectional views illustrating an embodiment of a method of manufacturing a memory device in FIG. 19;

FIG. 23 is a cross-sectional view illustrating another example embodiment of a memory device in accordance with the present invention; and

FIGS. 24 to 27 are cross-sectional views illustrating an embodiment of a method of manufacturing a memory device in FIG. 23.

### DESCRIPTION OF THE EMBODIMENTS

Embodiments of the present invention will be described with reference to the accompanying drawings. The present invention can, however, be embodied in many different forms and should not be construed as limited to the embodiments set forth herein. The principles and features of this invention can be employed in varied and numerous embodiments without departing from the scope of the present invention. In the drawings, the size and relative sizes of layers and regions can be exaggerated for clarity. The drawings are not necessarily to scale. Like reference numerals designate like elements throughout the drawings.

It will also be understood that when an element or layer is referred to as being “on,” “connected to” and/or “coupled to” another element or layer, the element or layer can be directly on, connected and/or coupled to the other element or layer or intervening elements or layers can be present. In contrast, when an element is referred to as being “directly on,” “directly connected to” and/or “directly coupled to” another element or layer, no intervening elements or layers are present. As used herein, the term “and/or” can include any and all combinations of one or more of the associated listed items.

It will also be understood that, although the terms first, second, etc. can be used herein to describe various elements, components, regions, layers and/or sections. These elements, components, regions, layers and/or sections should not be limited by these terms. These terms can be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device can be otherwise oriented (e.g., rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Embodiments of the present invention are described with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein, but are to include deviations in shapes that result, for example, from manufacturing. For example, a region illustrated as a rectangle will, typically, have rounded or curved features. Thus, the regions illustrated in the figures are schematic in nature of a device and are not intended to limit the scope of the present invention.

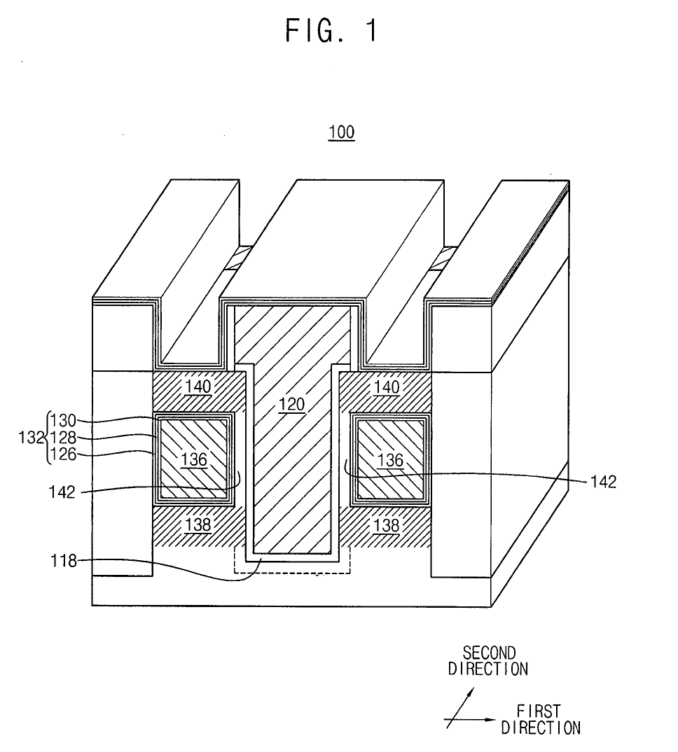

FIG. 1 is a cross-sectional view illustrating an example embodiment of a memory device in accordance with the present invention. Although FIG. 1 illustrates a non-volatile memory device, advantages of the present invention can be employed in a volatile memory device, such as, for example, a DRAM device or an SRAM device.

Referring to FIG. 1, a memory device 100 includes a first gate insulating layer 118, a first gate electrode 120, a second gate insulating layer 132, a second gate electrode 136, a pair of first source/drain regions 138, a pair of second source/drain regions 140, and a pair of channel regions 142.

The first gate electrode 120 can include a conductive material such as doped polysilicon or metal. The first gate electrode 120 can extend in a second direction substantially perpendicular to a first direction. The first gate insulating layer 118 is formed on both sidewalls of the first gate electrode 120. In addition, the first gate insulating layer 118 can be a single-layered structure. Alternatively, the first gate insulating layer 118 can be a multi-layered structure, such as a silicon oxide/silicon nitride/silicon oxide (ONO) layer as an example.

The first gate insulating layer 118 can be formed by a thermal oxidation process. Alternatively, the first gate insulating layer 118 can be formed using a high dielectric material having a relatively high dielectric constant greater than about 3.9, i.e., a dielectric constant of silicon oxide. The high dielectric material can be aluminum oxide, hafnium oxide, or zirconium oxide.

The pair of channel regions 142 can be horizontally disposed at a central portion of the first gate electrode 120. The pair of channel regions 142 can vertically extend such that the pair of channel regions 142 can make contact with the first gate insulating layer 118.

The pair of first source/drain regions 138 can extend horizontally along a lower portion of the first gate electrode 120. The pair of first source/drain regions 138 can horizontally extend such that the pair of first source/drain regions 138 makes contact with the first gate insulating layer 118.

The pair of second source/drain regions 140 can extend horizontally along an upper portion of the first gate electrode 120. The pair of second source/drain regions 140 can horizontally extend such that the pair of second source/drain regions 140 makes contact with the first gate insulating layer 118.

The first source/drain region 138 and the second source/drain region 140 can include a first impurity. The first impurity can be an N-typed impurity providing electrons. For example, the N-typed impurity can be nitrogen (N), phosphorus (P), arsenic (As), antimony (Sb) or bismuth (Bi). Alternatively, the first impurity can be a P-typed impurity providing electron holes. The P-typed impurity can be boron (B), aluminum (Al), gallium (Ga) or indium (In). The channel region 142 can include a second impurity having an opposite polarity to the first impurity. In an example embodiment, in case that the first impurity is a P-typed impurity, the second impurity can be an N-typed impurity. In another example embodiment, in case that the first impurity is an N-typed impurity, the second impurity can be a P-typed impurity.

The second gate electrode 136 can include a conductive material, such as doped polysilicon or metal. The second gate electrode 136 can extend in the second direction. The second gate electrode 136 can be enclosed by the second gate insulating layer 132. The second gate insulating layer 132 can include a first oxide layer 126, a nitride layer 128, and a second oxide layer 130.

Particularly, the second gate electrode 136 enclosed by the second gate insulating layer 132 can be disposed between the first source/drain region 138 and the second source/drain region 140 such that the second gate electrode 136 can horizontally correspond to the channel region 142. Here, the second gate insulating layer 132 can make contact with the first source/drain region 138, the second source/drain region 140 and the channel region 142.

Hereinafter, an embodiment of a method of manufacturing the memory device 100 in FIG. 1 is described.

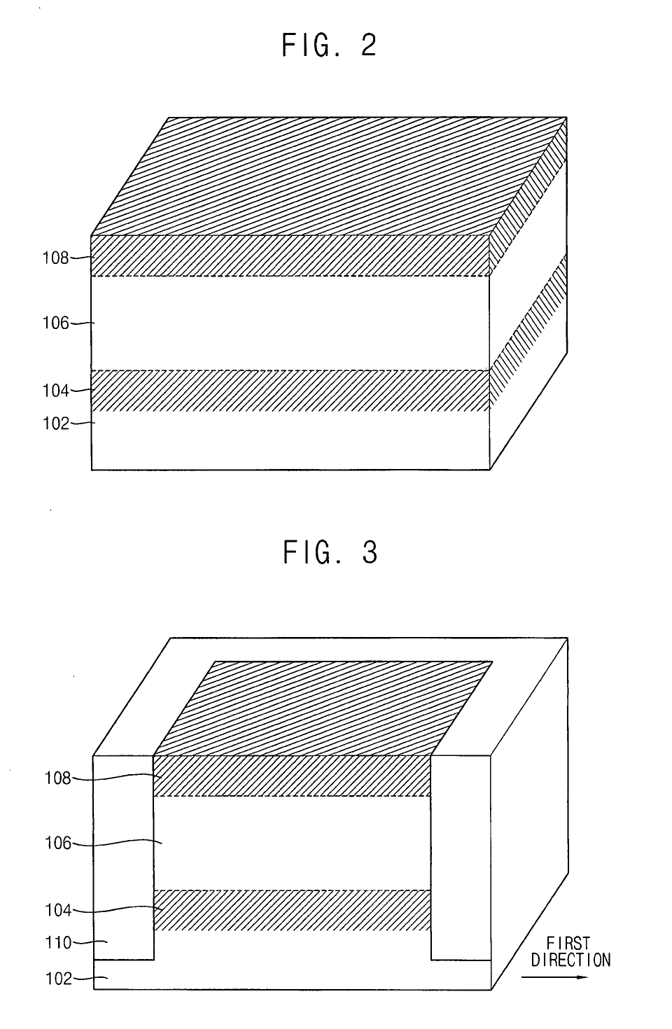

FIGS. 2 to 14 are cross-sectional views illustrating the method of manufacturing a memory device in FIG. 1. Although FIGS. 2 to 14 illustrates a method of manufacturing a non-volatile memory device, advantages of the present invention can be employed in a method of manufacturing a volatile memory device such as a DRAM or an SRAM.

Referring to FIG. 2, a first single crystalline layer 104, a sacrificial single crystalline layer 106 and a second single crystalline layer 108 are subsequently formed on a silicon substrate 102. The first and second single crystalline layers 104 and 108 can include silicon. The first and second single crystalline layers 104 and 108 can be doped with the first impurity. The sacrificial single crystalline layer 106 can include a material substantially different from silicon. In various embodiments, the material can be grown using an epitaxial growth process. For example, the material can be a silicon-germanium epitaxial layer.

The first single crystalline layer 104 can be formed by doping the first impurity into a surface portion of the silicon substrate 102. The sacrificial single crystalline layer 106 can be formed by an epitaxial growth process employing the first single crystalline layer 104 as a seed. And the second single crystalline layer 108 can be formed by an epitaxial growth process employing the sacrificial single crystalline layer 106 as a seed.

Referring to FIG. 3, the second single crystalline layer 108, the sacrificial single crystalline layer 106, the first single crystalline layer 104, and the silicon substrate 102 are etched to form a trench. Here, a bottom face of the trench can be substantially lower than a lower face of the first single crystalline layer 104.

Thereafter, the trench is filled with silicon oxide to form an isolation layer 110. Thus, an active region enclosed by the isolation layer 110 is formed. The active region can extend in a first direction.

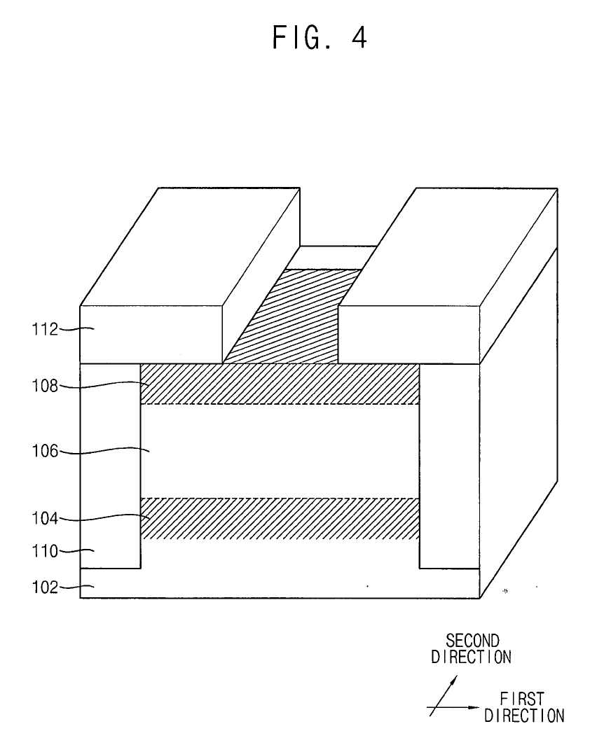

Referring to FIG. 4, a mask layer 112 extending in a second direction substantially perpendicular to the first direction is formed on the active region and the isolation layer 110. The mask layer 112 can be formed using silicon nitride, for example. Although not illustrated in FIG. 4, a buffer layer including silicon oxide can be formed under the mask layer 112.

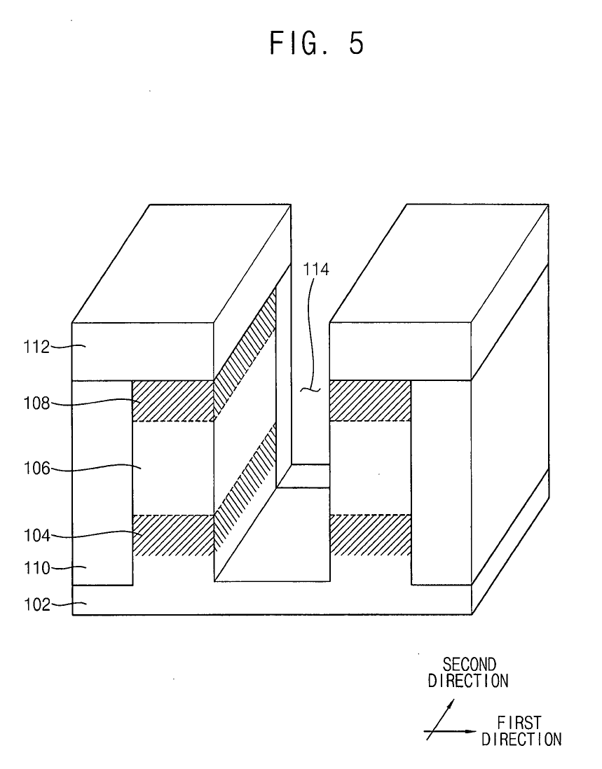

Referring to FIG. 5, the active region and isolation layer 110 are etched using the mask layer 112 as an etch mask. Thus, a first groove 114 extending in the second direction can be formed at the active region and the isolation layer 110.

Here, a bottom face of the first groove 114 can be substantially lower than a lower face of the first single crystalline layer 104. Thus, the first single crystalline layer 104, the sacrificial single crystalline layer 106, and the second single crystalline layer 108 can be exposed from both sidewalls of the first groove 114. In addition, the silicon substrate 102 can be exposed from the bottom face of the first groove 114.

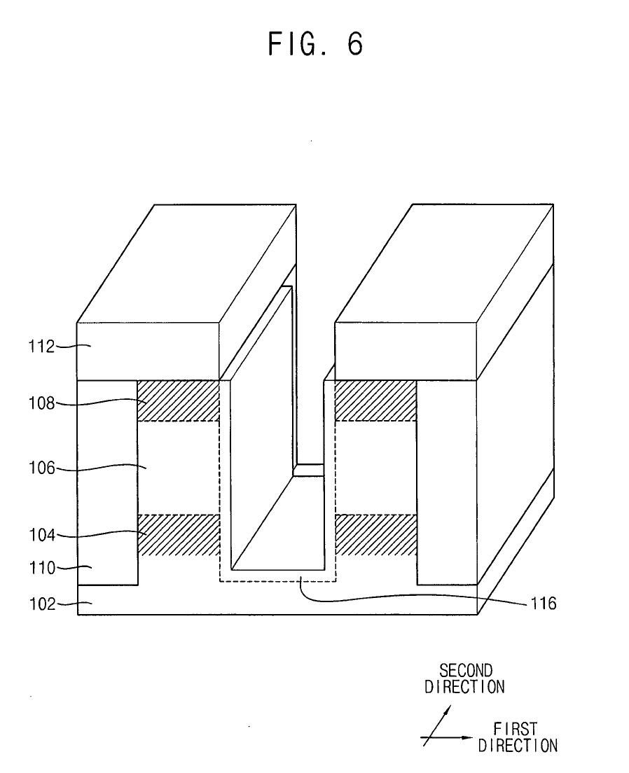

Referring to FIG. 6, an epitaxial growth process is performed on an inner face of the first groove 114 so that a single crystalline thin film 116 including silicon can be formed. Particularly, the single crystalline thin film 116 including silicon can grow from the silicon substrate 102, the first single crystalline layer 104, the sacrificial single crystalline layer 106, and the second single crystalline layer 108 exposed through the first groove 114. However, the single crystalline thin film 116 including silicon does not grow from the isolation layer 110 exposed through the first groove 114.

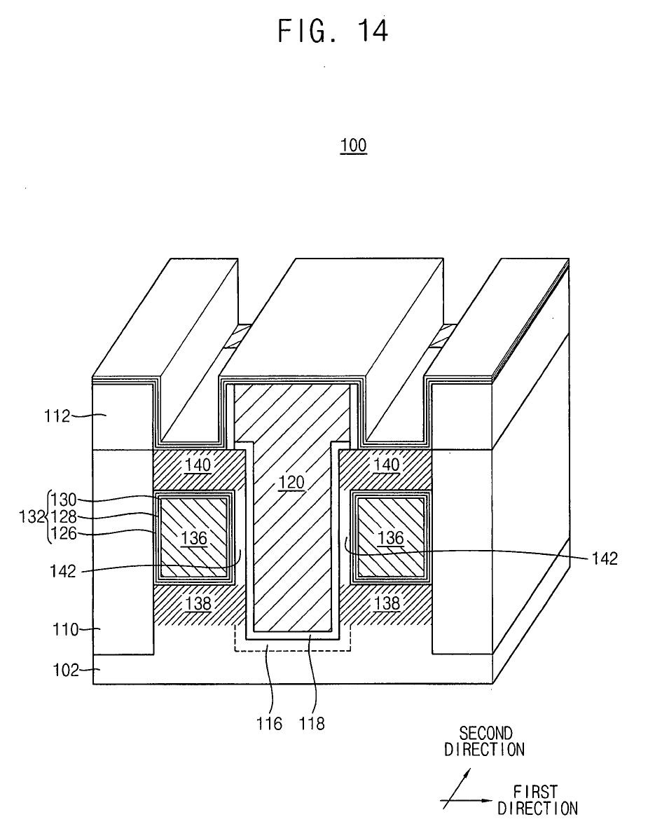

A thickness of a channel region 142 (see FIG. 14) that is subsequently formed can be determined by a thickness of the single crystalline thin film 116. Thus, it is necessary to control conditions of the epitaxial growth process such that the single crystalline thin film 116 has an optimal thickness. Here, a second impurity having an opposite polarity to the first impurity can be doped into both side portions of the single crystalline thin film 116.

The channel region 142 (see FIG. 14) that is subsequently formed can have a relatively large lattice constant because the channel region 142 (see FIG. 14) corresponds to a portion of the single crystalline thin film 116 growing from the sacrificial single crystalline layer 106, which can include a material such as silicon-germanium having a relatively large lattice constant. Thus, an electric reliability of the channel region 142 (see FIG. 14) can be relatively superior.

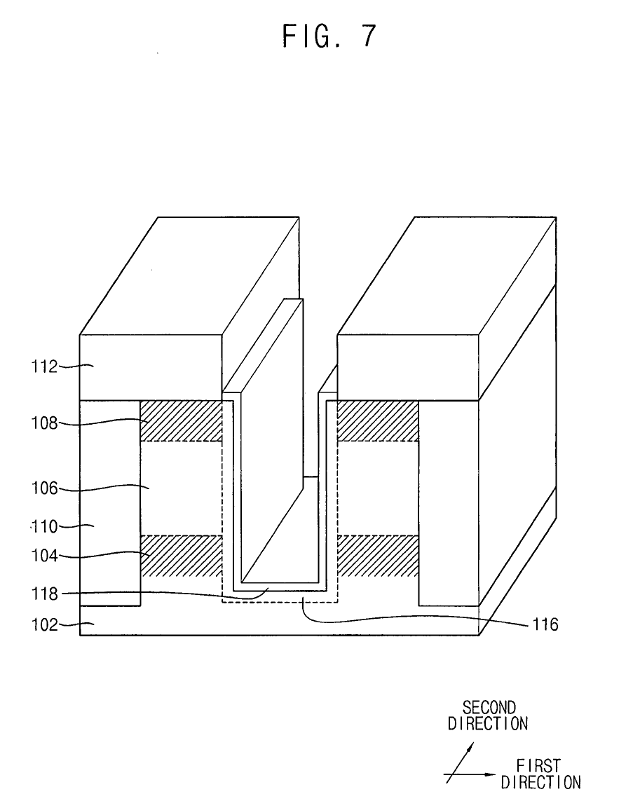

Referring to FIG. 7, a first gate insulating layer 118 is formed on the single crystalline thin film 116. The first gate insulating layer 118 can be a single-layered structure. Alternatively, the first gate insulating layer 118 can be a multi-layered structure, such as a silicon oxide/silicon nitride/silicon oxide (ONO) layer.

In an example embodiment, the first gate insulating layer 118 can be formed by a thermal oxidation process. In this case, the first gate insulating layer 118 can include silicon oxide. In addition, the first gate insulating layer 118 can be selectively formed on the single crystalline thin film 116. As described above, the thickness of the single crystalline thin film 116 can determine the thickness of the channel region 142 (see FIG. 14) that is subsequently formed. Thus, preferably, the thermal oxidation process is not excessively performed such that the thickness of the single crystalline thin film 116 cannot be excessively reduced.

Alternatively, the first gate insulating layer 118 can be formed using a high dielectric material having a relatively high dielectric constant greater than about 3.9, i.e., a dielectric constant of silicon oxide. The high dielectric material can be aluminum oxide, hafnium oxide or zirconium oxide. In this case, the first gate insulating layer 118 can be formed on the mask layer 112 and the isolation layer 110 as well as the single crystalline thin film 116.

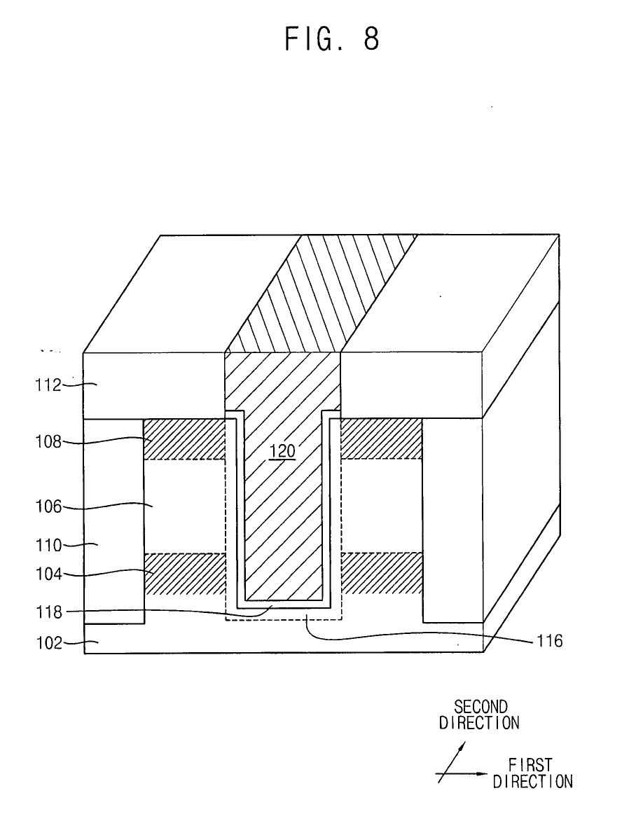

Referring to FIG. 8, a first gate electrode 120 is formed on the first gate insulating layer 118. A central portion of the first gate electrode 120 can horizontally correspond to the sacrificial single crystalline layer 106. A lower portion of the first gate electrode 120 can horizontally correspond to the first single crystalline layer 104. An upper portion of the first gate electrode 120 can horizontally correspond to the second single crystalline layer 108.

The first gate electrode 120 can be formed using a conductive material such as metal or doped polysilicon. Particularly, a conductive layer is formed on the first gate insulating layer 118 and the mask layer 112. A planarization process such as a chemical mechanical polishing (CMP) process is then performed on the conductive layer until the mask layer 112 is exposed so that the first gate electrode 120 can be formed.

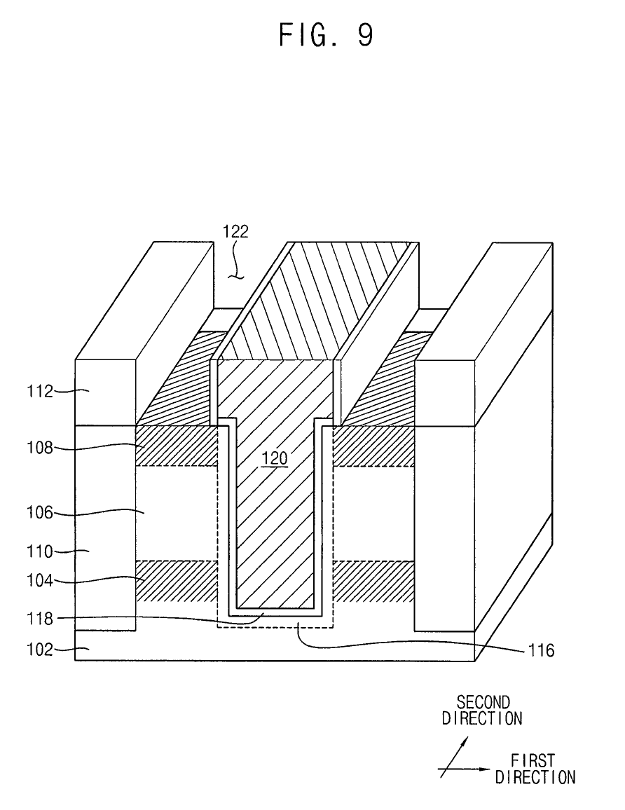

Referring to FIG. 9, the mask layer 112 is etched so that a second groove 122 exposing a portion of the second single crystalline layer 108 and a portion of the isolation layer 110 can be formed. The second groove 122 can extend in the second direction.

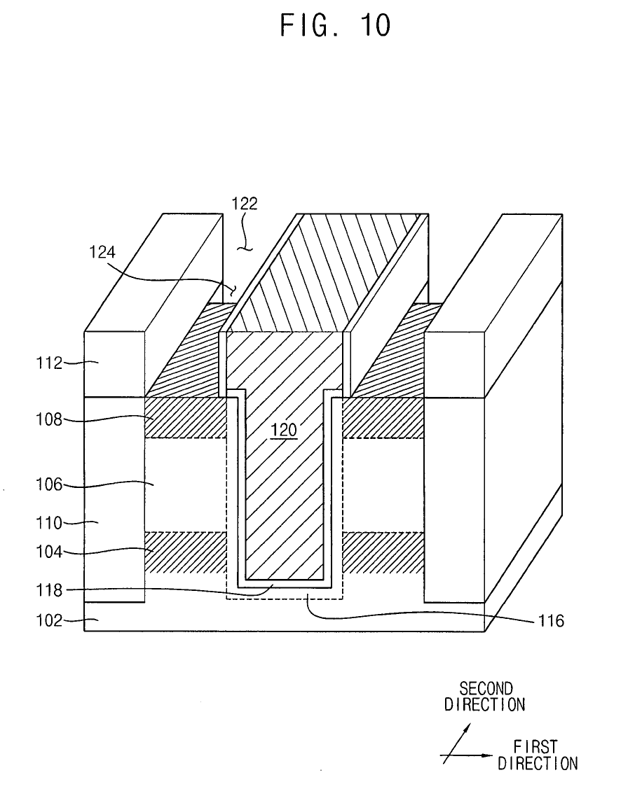

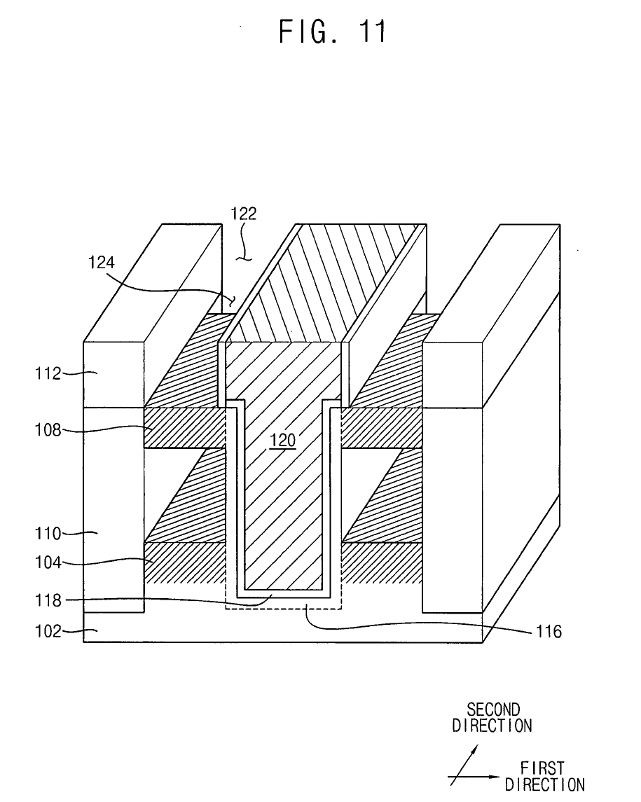

Referring to FIG. 10, a portion of the isolation layer 110 exposed from a bottom face of the second groove 122 is etched so that a recess 124 can be formed. The recess 124 can be in communication with the second groove 122. In addition, the recess 124 can expose the sacrificial single crystalline layer 106.

Referring to FIG. 11, the sacrificial single crystalline layer 106 of FIG. 10 is selectively removed through the recess 124. As described above, the sacrificial single crystalline layer 106 includes silicon germanium substantially different from silicon included in the first and single crystalline layers 104 and 108. Thus, the sacrificial single crystalline layer 106 can be selectively removed. As an example, the sacrificial single crystalline layer 106 can be removed by a wet etching process.

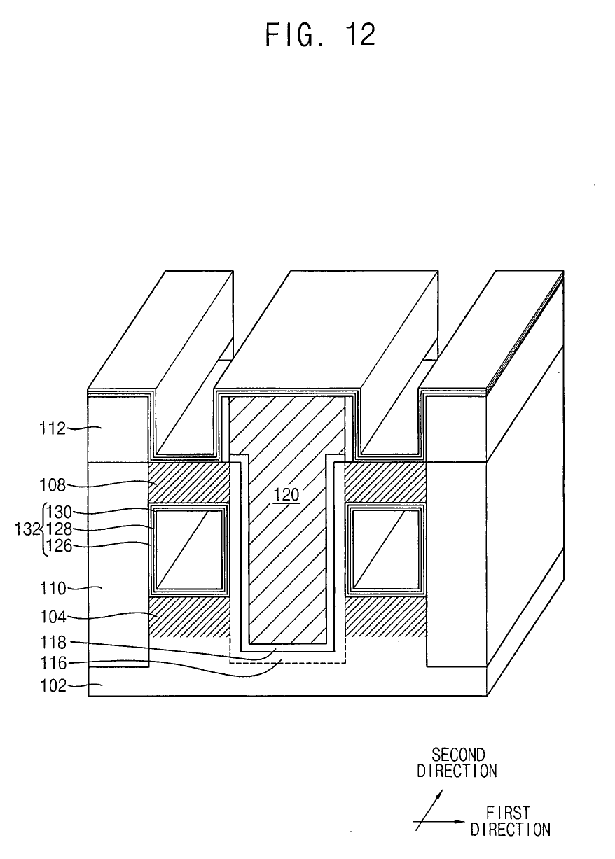

Referring to FIG. 12, a second gate insulating layer 132 is formed on an entire surface exposed after the sacrificial single crystalline layer 106 is removed. Particularly, the second gate insulating layer 132 is continuously formed on an inner face of a space formed by removing the sacrificial single crystalline layer 106, an inner face of the recess 124, an inner face of the second groove 122 and an upper face of the mask layer 112.

The second gate insulating layer 132 includes a first oxide layer 126, a nitride layer 128, and a second oxide layer 130. In an example embodiment, the first oxide layer 126, the nitride layer 128, and the second oxide layer can be formed by a deposition process. In another example embodiment, the first oxide layer 126 can be formed by a thermal oxidation process and the nitride layer 128 and second oxide layer 130 can be formed by a deposition process. In this case, preferably, the thermal oxidation process cannot be excessively performed such that the thickness of the single crystalline thin film 116 cannot be excessively reduced.

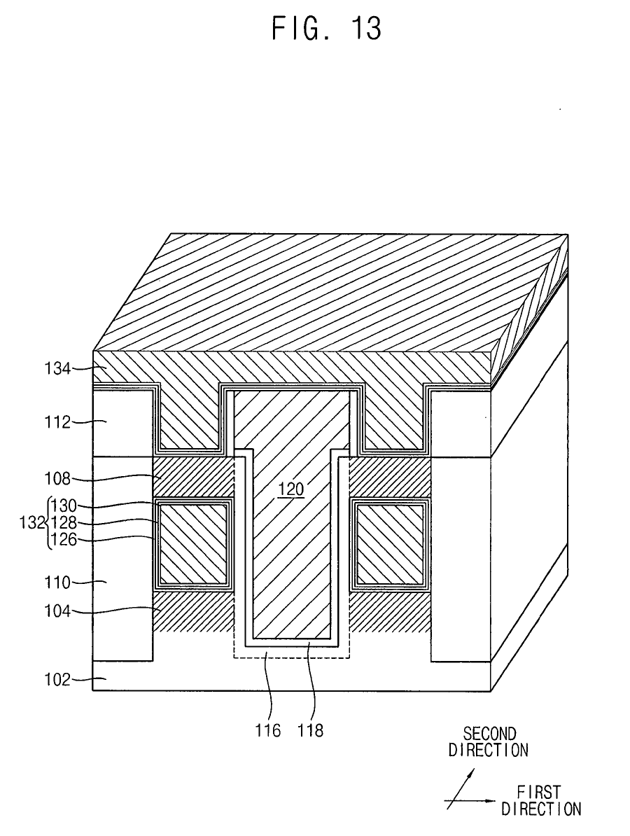

Referring to FIG. 13, a conductive layer 134 can be formed on the second gate insulating layer 132 from a conductive material, such as doped polysilicon or metal. Here, the conductive layer 134 can substantially fill up the space formed by removing the sacrificial single crystalline layer 106, the recess 124, and the second groove 122.

Referring to FIG. 14, the conductive layer 134 is etched to form a second gate electrode 136 filling up the recess 124 and the second groove 122. The second gate electrodes 136 can be spaced apart from each other along the first direction.

The first impurity doped into the first single crystalline layer 104 and the second single crystalline layer 108 can be diffused to the single crystalline thin film 116 in the above described processes. Impurities can be inevitably diffused because processes for forming a semiconductor device are typically performed at a relatively high temperature.

Accordingly, as illustrated in FIG. 14, the first impurity in the first single crystalline layer 104 can be diffused to the single crystalline thin film 116 so that a pair of first source/drain regions 138 can be formed. Particularly, the pair of first source/drain regions 138 makes contact with the first gate insulating layer 118. The pair of first source/drain regions 138 can horizontally extend. In addition, the pair of first source/drain regions 138 can extend horizontally along a lower portion of the first gate insulating layer 118.

The first impurity included in the second single crystalline layer 108 can be partially diffused to the single crystalline thin film 116 so that a pair of second source/drain regions 140 can be formed. Particularly, the pair of second source/drain regions 140 can make contact with the first gate insulating layer 118. The pair of the second source/drain regions 140 can horizontally extend. In addition, the pair of second source/drain regions 140 can extend horizontally along an upper portion of the first gate insulating layer 118.

In addition to forming the pair of first source/drain regions 138 and the pair of second source/drain regions 140, the process can include forming portions of the single crystalline thin film 116 located there between as the pair of channel regions 142.

In this embodiment, the pair of channel regions 142 can vertically extend between the first gate insulating layer 118 and the second gate insulating layer 132. In addition, the pair of channel regions 142 can extend horizontally along the second gate electrode 136 and a central portion of the first gate electrode 120.

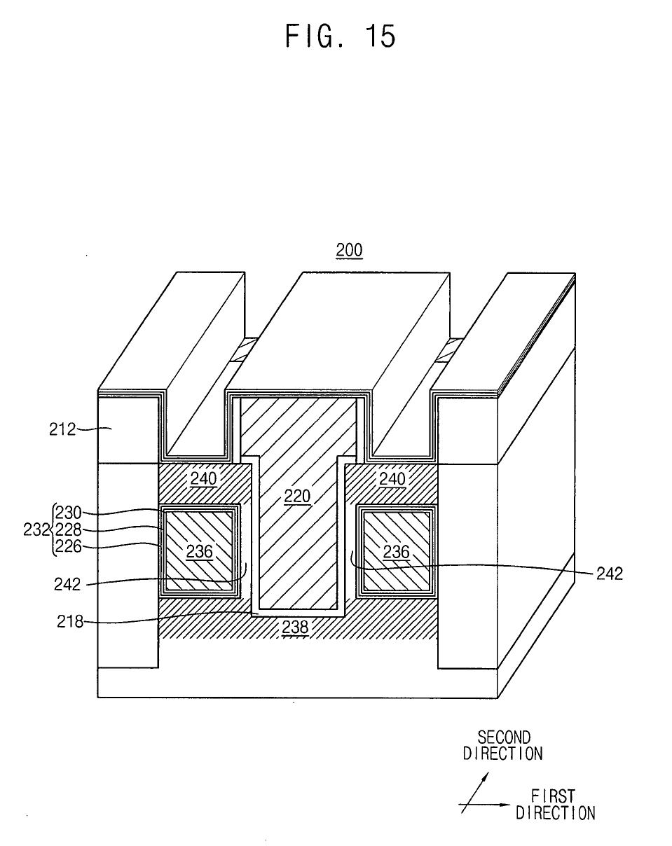

FIG. 15 is a cross-sectional view illustrating another example embodiment of a memory device in accordance with the present invention. Although FIG. 5 illustrates a non-volatile memory device, advantages of the present invention can be employed in a volatile memory device such as a DRAM or an SRAM.

Referring to FIG. 15, a memory device 200 includes a first gate insulating layer 218, a first gate electrode 220, a second gate insulating layer 232, a second gate electrode 236, a first source/drain region 238, a pair of second source/drain regions 240, and a pair of channel regions 242.

The memory device 200 can be substantially the same as the memory device 100 in FIG. 1 except for the first source/drain region 238. Thus, any repetitive explanation will be omitted.

The first source/drain region 238 extends horizontally along a lower portion of the first gate electrode 220, in a first direction. In addition, the first source/drain region 238 makes contact with the first gate insulating layer 218. The first source/drain region 238 can horizontally extend such that a portion of the first source/drain region 238 is located under the first gate electrode 220.

The first source/drain region 238 can be doped with an impurity having an opposite polarity to an impurity doped into a channel region 242. In an example embodiment, in case that an N-typed impurity is doped into the channel region 242, a P-typed impurity can be doped into the first source/drain region 238. In another example embodiment, in case that the P-typed impurity is implanted into the channel region 242, the N-typed impurity can be doped into the first source/drain region 238.

Hereinafter, an embodiment of a method of manufacturing the memory device 200 in FIG. 15 is described.

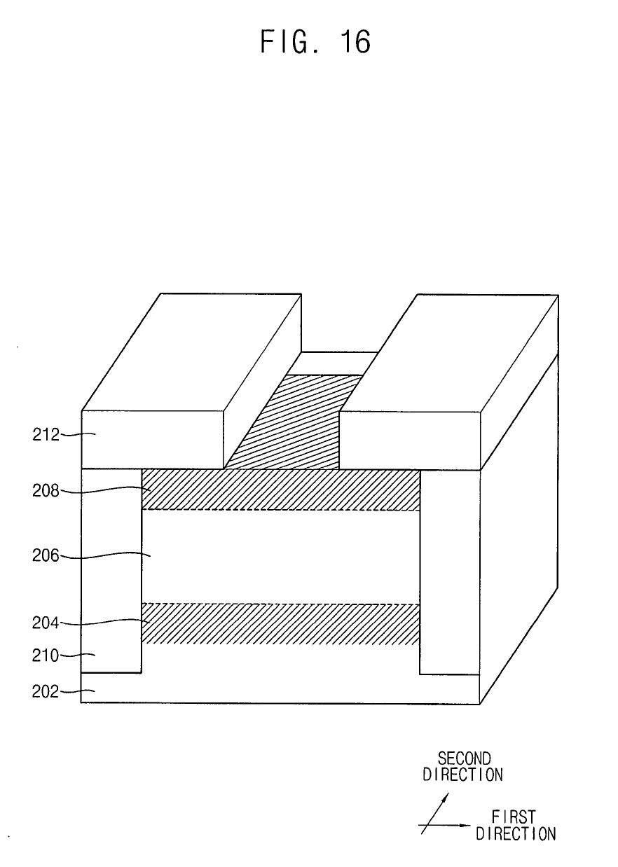

FIGS. 16 to 18 are cross-sectional views illustrating the method of manufacturing a memory device in FIG. 15. Although FIGS. 16 to 18 illustrate a method of manufacturing a non-volatile memory device, advantages of the present invention can be employed in a method of manufacturing a volatile memory device such as a DRAM or an SRAM.

Referring to FIG. 16, a mask layer 212 extending in a second direction substantially perpendicular to the first direction is formed on an active region and an isolation layer 210 by performing processes substantially the same as those illustrated with respect to FIGS. 2 to 4.

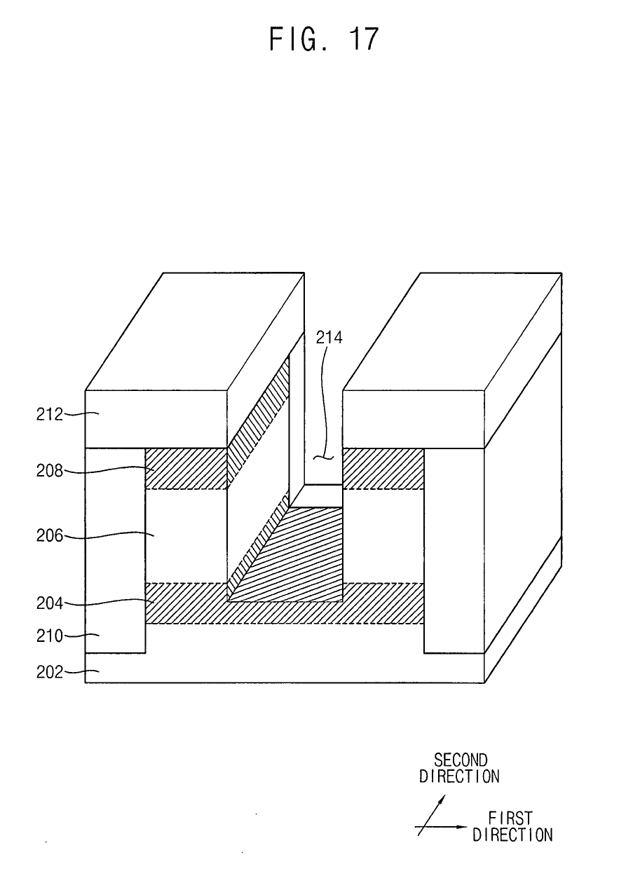

Referring to FIG. 17, the active region and the isolation layer 210 are etched using the mask layer 212 as an etch mask. Thus, a first groove 214 extending in the second direction can be formed at the active region and the isolation layer 210.

Here, a bottom face of the first groove 214 can be substantially higher than a lower face of the first single crystalline layer 204. Thus, both sidewalls of the first groove 214 can expose the first single crystalline layer 204, the sacrificial single crystalline layer 206, and the second single crystalline layer 208. In addition, a bottom face of the first groove 214 can expose the first single crystalline layer 204.

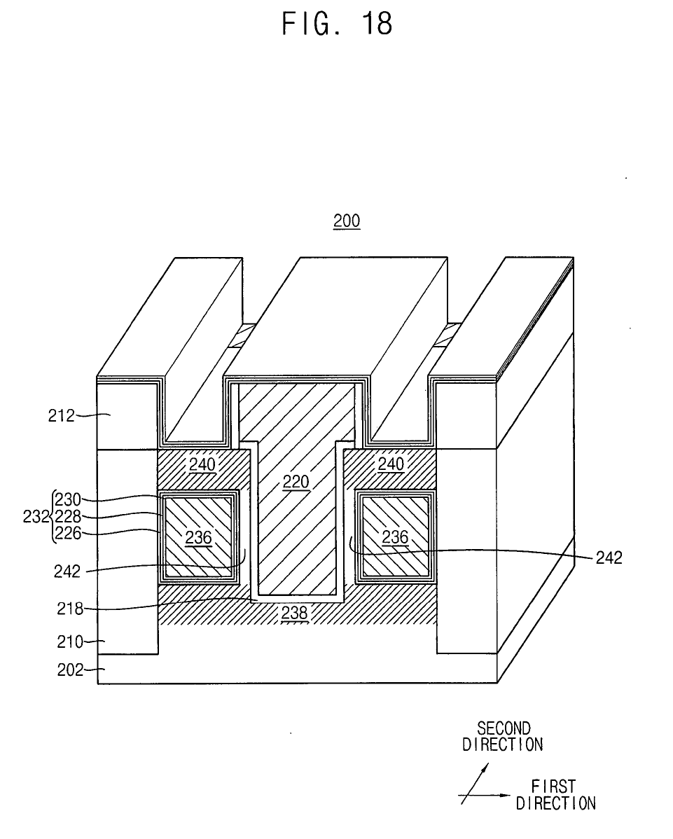

Referring to FIG. 18, processes substantially the same as those illustrated with respect to FIGS. 6 to 14 are performed. Thus, the memory device 200 including a first source/drain region 238, a first gate electrode 220, a first gate insulating layer 218, a pair of second source/drain regions 240, a pair of channel regions 242, a second gate insulating layer 232, and a second gate electrode 236 can be formed.

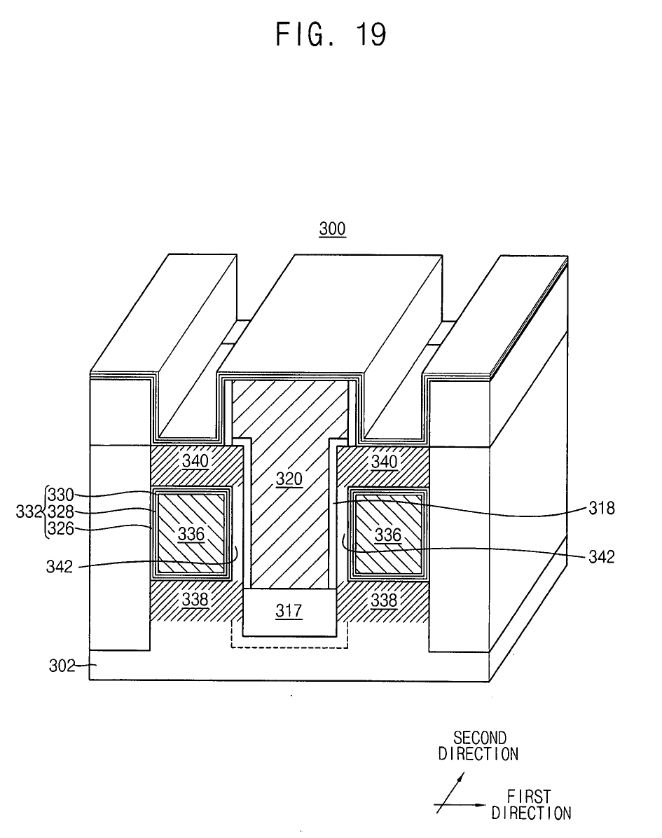

FIG. 19 is a cross-sectional view illustrating another example embodiment of a memory device in accordance with the present invention. Although FIG. 19 illustrates a non-volatile memory device, advantages of the present invention can be employed in a volatile memory device such as a DRAM or an SRAM.

Referring to FIG. 19, a memory device 300 includes a first gate insulating layer 318, a first gate electrode 320, a second gate insulating layer 332, a second gate electrode 336, a pair of first source/drain regions 338, a pair of second source/drain regions 340, a pair of channel regions 342, and an insulating layer 317.

The memory device 300 can be substantially the same as the memory device 100 in FIG. 1 except for an insulating layer 317. Thus, any repetitive explanation will be omitted.

The insulating layer 317 can include an insulating material such as silicon nitride or silicon oxide. The insulating layer 317 can extend in a second direction. The insulating layer 317 can be located under the first gate electrode 320. The insulating layer 317 can make contact with the pair of first source/drain regions 338 horizontally.

Here, the memory device 300 can employ a horizontally extending first source/drain region (see FIG. 15) having a portion located under the insulating layer 317 instead of the pair of first source/drain regions 338.

Hereinafter, an embodiment of a method of manufacturing the memory device 300 in FIG. 19 is described.

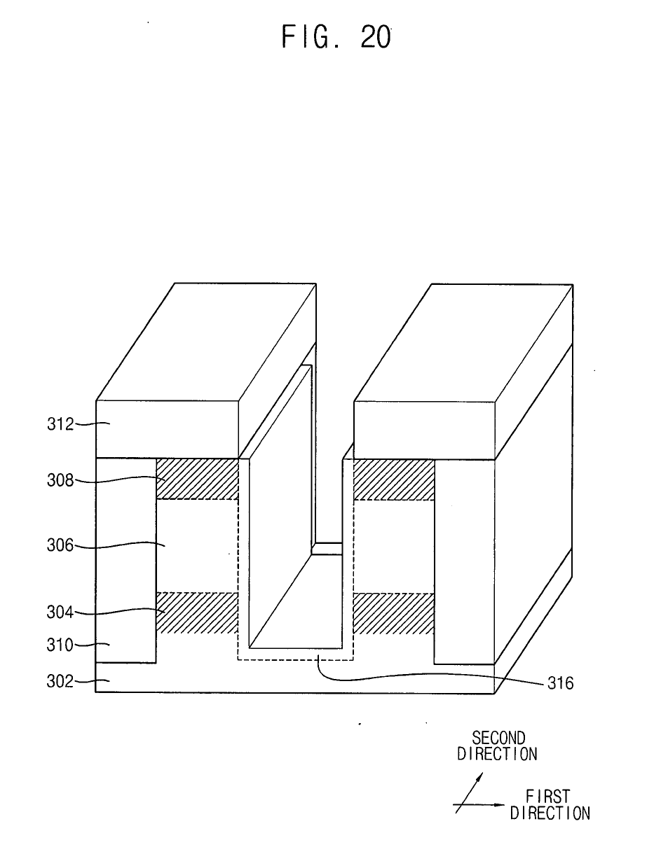

FIGS. 20 to 22 are cross-sectional views illustrating the method of manufacturing a memory device in FIG. 19. Although FIGS. 20 to 22 illustrate a method of manufacturing a non-volatile memory device, advantages of the present invention can be employed in a method of manufacturing a volatile memory device such as a DRAM or an SRAM.

Referring to FIG. 20, a single crystalline thin film 316 is formed by performing processes substantially the same as those illustrated with respect to FIGS. 2 to 6. That is, the active region and the isolation layer 310 are etched using the mask layer 312 as an etch mask. Thus, a first groove 314 extending in the second direction can be formed at the active region and the isolation layer 310.

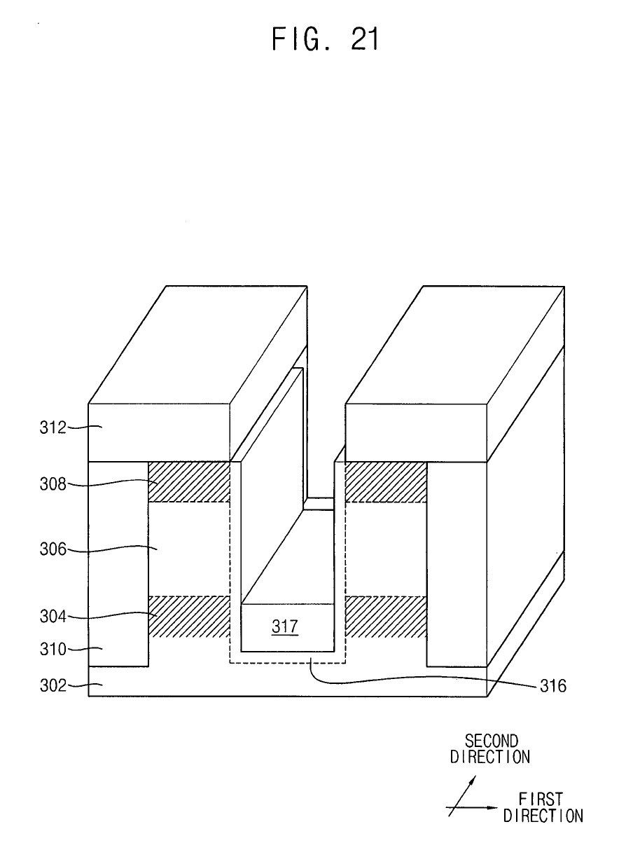

Referring to FIG. 21, an insulating material such as silicon oxide or silicon nitride is deposited on the single crystalline thin film 316 and an isolation layer 310 and then an etching process such as an etch-back process is performed to form an insulating layer 317. Here, the insulating layer 317 can horizontally correspond to the first single crystalline layer 304. In addition, the insulating layer 317 can extend in second direction on the single crystalline thin film 316 and the isolation layer 310.

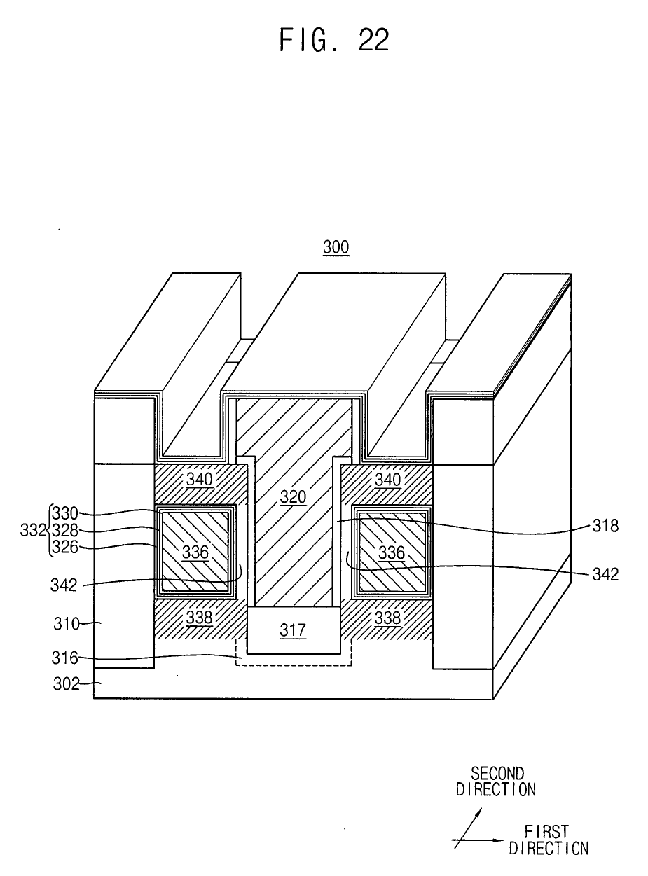

Referring to FIG. 22, processes substantially the same as those illustrated with respect to FIGS. 7 to 14 are performed so that a memory device 300 including a first gate insulating layer 318, a first gate electrode 320, a second gate insulating layer 332, a second gate electrode 336, a pair of first source/drain regions 338, a pair of second source/drain regions 340, a pair of channel regions 342, and an insulating layer 317 can be formed.

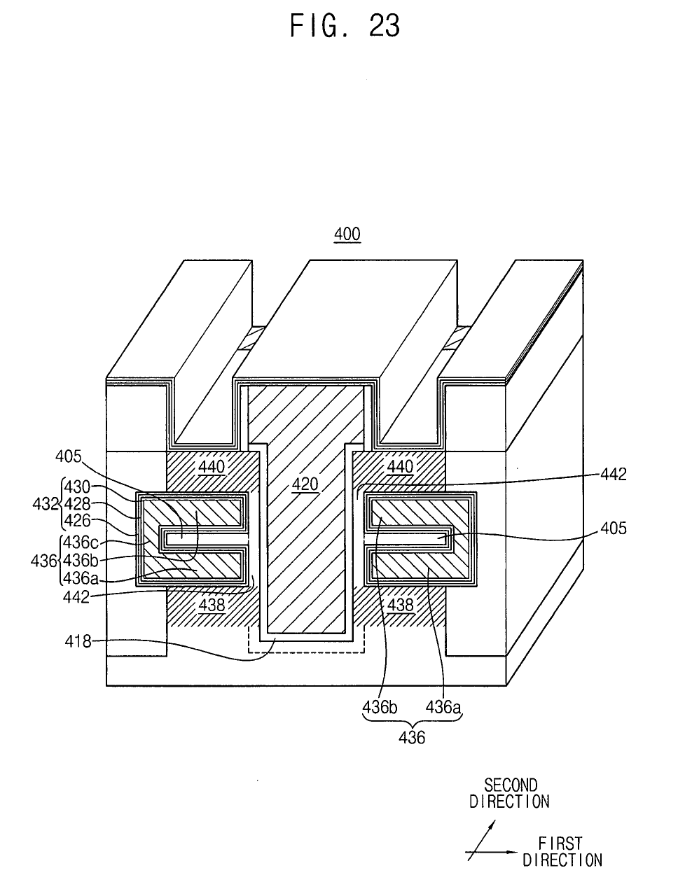

FIG. 23 is a cross-sectional view illustrating an example embodiment of a memory device in accordance with present invention. Although FIG. 23 illustrates a non-volatile memory device, advantages of the present invention can be employed in a volatile memory device such as a DRAM or an SRAM.

Referring to FIG. 23, a memory device 400 includes a first gate insulating layer 418, a first gate electrode 420, a second gate insulating layer 432, a second gate electrode 436, a pair of first source/drain regions 438, a pair of second source/drain regions 440, a pair of channel regions 442, and a single crystalline interlayer 405.

The memory device 400 is substantially the same as the memory device 100 in FIG. 1 except for the second gate electrode 436, the second gate insulating layer 432 and the single crystalline interlayer 405. Thus, any repetitive explanation will be omitted.

The second gate electrode 436 can be divided into a lower portion 436a, an upper portion 436b, and a connection portion 436c. The lower portion 436a and the upper portion 436b can be vertically spaced apart from each other in an active region. However, the lower portion 436a and the upper portion 436b can be connected to each other in a field region corresponding to an isolation layer 410 by a connection portion 436c that vertically extends. The second gate electrode 436 can extend in a second direction substantially perpendicular to a first direction in which the active region extends.

The second gate insulating layer 432 has a shape enclosing an outer face of the second gate electrode 436. In addition, the second gate insulating layer 432 can include a first oxide layer 426, a nitride layer 428 and a second oxide layer 430. That is, the second gate insulating layer 432 can be an ONO layer.

The single crystalline interlayer 405 is formed between the lower portion 436a and the upper portion 436b of the second gate electrode 436 enclosed by the second gate insulating layer 432. A length of the channel 442 can be increased by forming the single crystalline interlayer 405. The single crystalline interlayer 405 is horizontally connected to the channel region 442. In addition, the single crystalline interlayer 405 can include single crystalline silicon.

Here, the memory device 400 can employ a horizontally extending first source/drain region (see FIG. 15) having a portion located under the insulating layer 317 instead of the pair of first source/drain regions 438.

In addition, the memory device 400 can further include an insulating layer (see FIG. 19) located under a first gate electrode and horizontally connected to a pair of first source/drain regions.

Hereinafter, an embodiment of a method of manufacturing the memory device in FIG. 23 is described.

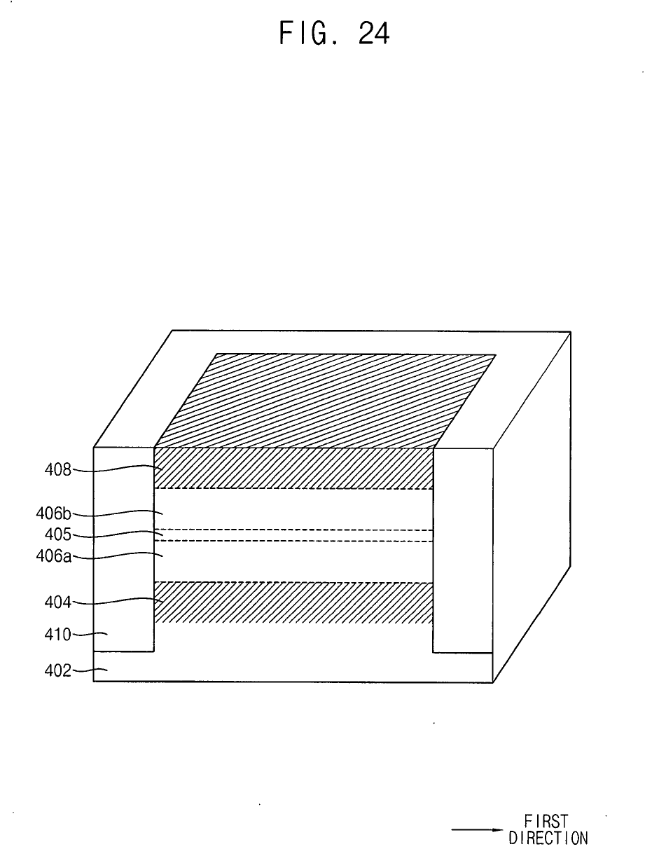

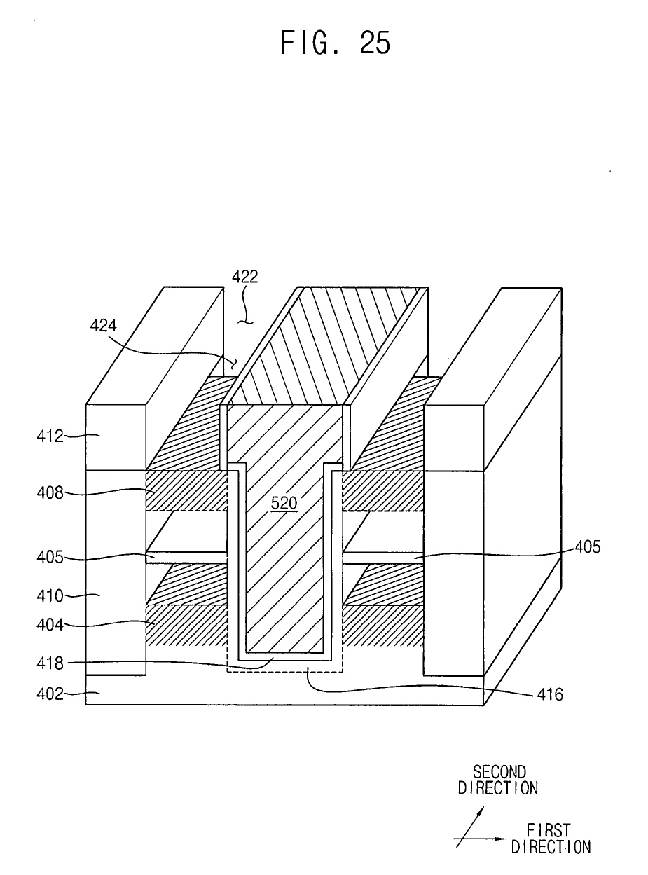

FIGS. 24 to 27 are cross-sectional views illustrating the method of manufacturing a memory device in FIG. 23. Although FIGS. 24 to 27 illustrate a method of manufacturing a non-volatile memory device, advantages of the present invention can be employed in a method of manufacturing a volatile memory device such as a DRAM or an SRAM.

Referring to FIG. 24, a first single crystalline layer 404, a lower sacrificial single crystalline layer 406a, a single crystalline interlayer 405, an upper sacrificial single crystalline layer 406a, and a second single crystalline layer 408 are subsequently formed on a silicon substrate 402. The first and second single crystalline layers 404 and 408 can include silicon. The first and second single crystalline layers 404 and 408 can be doped with a first impurity.

The lower and upper sacrificial single crystalline layers 406a and 406b can include a material substantially different from silicon. In various embodiments, the material can be grown using an epitaxial growth process. For example, the material can be a silicon-germanium epitaxial layer. The single crystalline interlayer 405 can include silicon.

The first single crystalline layer 404 can be formed by doping a first impurity into a surface portion of the silicon substrate 402. The lower sacrificial single crystalline layer 406a can be formed by an epitaxial growth process employing the first single crystalline layer 404 as a seed. The single crystalline interlayer 405 can be formed by an epitaxial growth process employing the lower single crystalline layer 404a as a seed. The upper sacrificial single crystalline layer 406b can be formed by an epitaxial growth process employing the single crystalline interlayer 405 as a seed. The second single crystalline layer 408 can be formed by an epitaxial growth process employing the upper sacrificial single crystalline layer 406b as a seed.

Thereafter, the second single crystalline layer 408, the upper sacrificial single crystalline layer 406b, the single crystalline interlayer 405, the lower sacrificial single crystalline layer 406a, the first single crystalline layer 404, and the silicon substrate 402 are etched to form a trench. Here, a bottom face of the trench can be substantially lower than a lower face of the first single crystalline layer 404.

The trench is filled with silicon oxide to form an isolation layer 410. Thus, an active region enclosed by the isolation layer 410 can be formed. The active region can extend in a first direction.

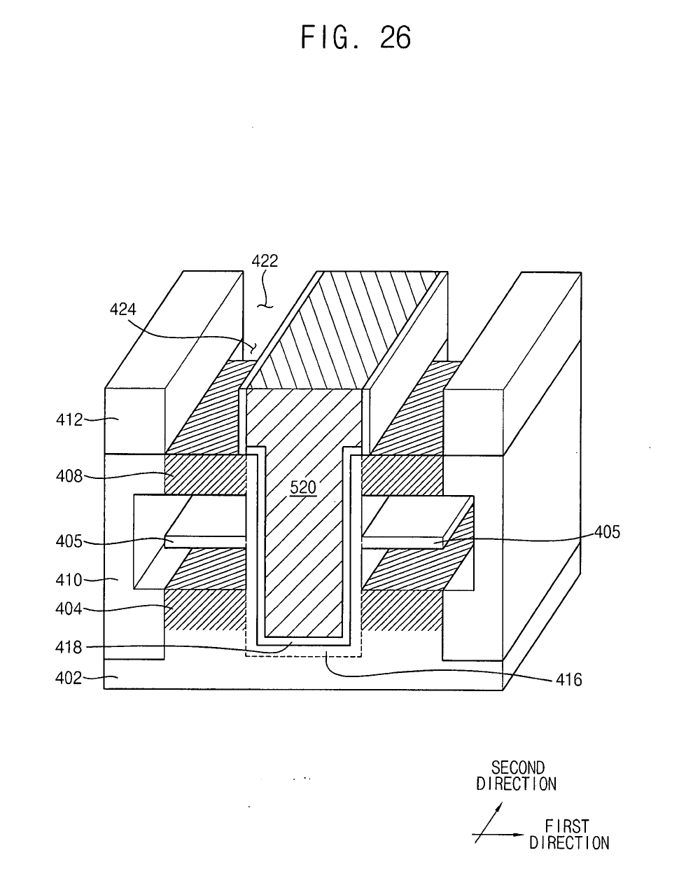

Referring to FIG. 25, processes substantially the same as those illustrated with respect to FIGS. 4 to 11 are performed. Thus, the lower sacrificial single crystalline layer 406a and the upper sacrificial single crystalline layer 406b are removed through the second groove 522 and the recess 524.

Referring to FIG. 26, an etching process such as a wet etching process can be performed on a portion of the isolation layer 410 exposed after the lower sacrificial single crystalline layer 406a and the upper sacrificial single crystalline layer 406b are removed. Thus, a size of a space formed by removing the lower sacrificial single crystalline layer 406a and the upper sacrificial single crystalline layer 406b can be enlarged.

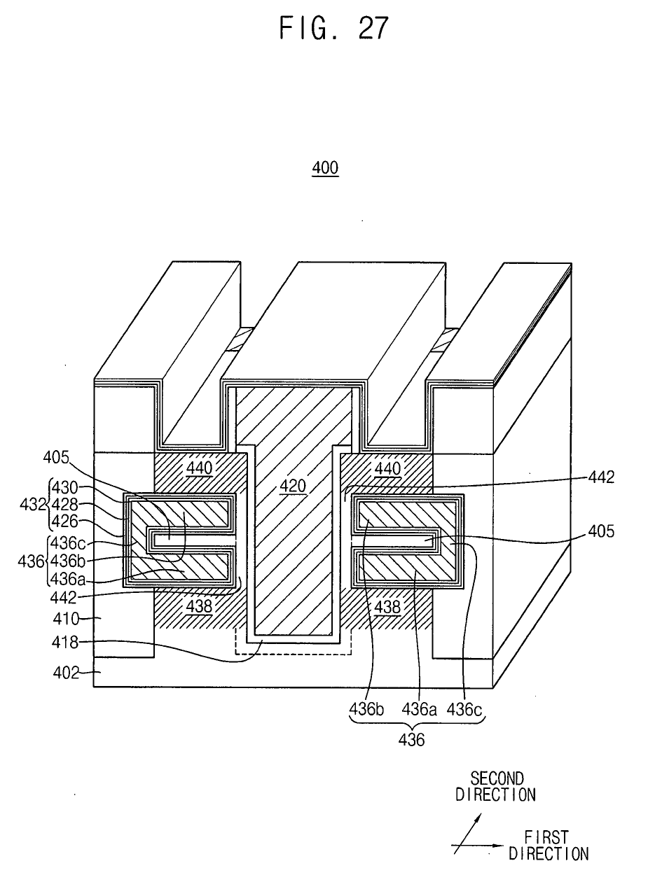

Referring to FIG. 27, processes substantially the same as those illustrated with respect to FIGS. 12 to 14 are performed so that a memory device 500 including the first gate insulating layer 518, the first gate electrode 520, the second gate insulating layer 532, the second gate electrode 536, a pair of first source/drain regions 538, a pair of second source/drain regions 540, a pair of channel regions 542, and the single crystalline interlayer 505 can be manufactured.

According to the present invention, a second gate insulating layer is an ONO layer. Thus, a memory device can be achieved using a charge trap characteristic of a nitride layer included in the ONO layer. In addition, charges stored in the ONO layer can be efficiently removed through a first gate electrode. Thus, efficiency in an erase operation of the memory device can be improved.

The foregoing embodiments are illustrative of aspects of the present invention and are not to be construed as limiting thereof. Although a few embodiments have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of aspects of the present invention, which is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A memory device comprising:
a first gate electrode having two sidewalls;
a first gate insulating layer provided on both sidewalls of the first gate electrode;
a pair of channel regions extending horizontally along a central portion of the first gate electrode, the pair of channel regions vertically extending such that the pair of channel regions makes contact with the first gate insulating layer;
a pair of first source/drain regions extending horizontally along a lower portion of the first gate electrode, the pair of first source/drain regions making contact with the first gate insulating layer;
a pair of second source/drain regions extending horizontally along an upper portion of the first gate electrode, the pair of second source/drain regions making contact with the first gate insulating layer;
a second gate electrode located between the first source/drain region and the second source/drain region, the second gate electrode extending horizontally adjacent to the channel region; and
a second gate insulating layer enclosing the second gate electrode, the second gate insulating layer being an ONO layer.

2. The memory device of claim 1, wherein the first and second source/drain regions include a first impurity and the channel region includes a second impurity having an opposite polarity to the first impurity.

3. The memory device of claim 1, wherein the pair of first source/drain regions is connected to each other beneath the first gate electrode.

4. The memory device of claim 1, further comprising an insulating layer beneath the first gate electrode.

5. The memory device of claim 1, further comprising:
a single crystalline interlayer vertically connected to the channel region,
wherein the second gate electrode has a structure enclosing the single crystalline interlayer.

6. The memory device of claim 5, wherein the second gate electrode includes an upper portion located on the single crystalline interlayer, a lower portion located beneath the single crystalline interlayer, and a connection portion located on a side portion of the single crystalline interlayer to connect the upper portion to the lower portion.

7. A method of manufacturing a memory device, the method comprising:
sequentially forming a first single crystalline layer, a sacrificial single crystalline layer and a second single crystalline layer at a substrate;
forming a groove having two sidewalls exposing the first single crystalline layer, the sacrificial single crystalline layer, and the second single crystalline layer;
forming a single crystalline thin film having a substantially uniform thickness on an inner face of the groove;
forming a first gate insulating layer having a substantially uniform thickness on the single crystalline thin film;
forming a first gate electrode on the first gate insulating layer to fill up the groove;
removing the sacrificial single crystalline layer;
forming an ONO layer on an inner face of a space formed by removing the sacrificial single crystalline layer; and
forming a second gate electrode on the ONO layer such that the second gate electrode fills up the space formed by removing the sacrificial single crystalline layer.

8. The method of claim 7, wherein the first and second single crystalline layers are doped with a first impurity.

9. The method of claim 8, wherein the single crystalline thin film is doped with a second impurity having an opposite polarity to the first impurity.

10. The method of claim 7, wherein a surface portion of the substrate is used as the first single crystalline layer and the sacrificial single crystalline layer, the second single crystalline layer, and the single crystalline thin film are formed by an epitaxial growth process.

11. The method of claim 7, further comprising:
forming an insulating layer on the single crystalline thin film before the first gate insulating layer is formed, the insulating layer extending horizontally along the first single crystalline layer.

12. The method of claim 11, wherein forming the insulating layer comprises:
forming a preliminary insulating layer on the single crystalline thin film by depositing an insulating material to fill up the groove and then etching the insulating material.

13. The method of claim 7, further comprising exposing the first single crystalline layer from a bottom face of the groove, wherein a pair of first source/drain regions are connected to each other.

14. The method of claim 7, further comprising exposing the substrate from a bottom face of the groove, wherein a pair of first source/drain regions are spaced apart from each other.

15. A method of manufacturing a memory device, the method comprising:
forming an active region at a substrate, the active region including a first single crystalline layer, a lower sacrificial single crystalline layer, a single crystalline interlayer, an upper sacrificial single crystalline layer, and a second single crystalline layer that are sequentially formed, including enclosing the active region with an isolation layer;
forming a groove in the active region and the isolation layer, the groove having two sidewalls that expose the first single crystalline layer, the lower sacrificial single crystalline layer, the single crystalline interlayer, the upper sacrificial single crystalline layer and the second single crystalline layer;
forming a single crystalline thin film on an inner face of the groove, the single crystalline layer having a substantially uniform thickness;
forming a first gate insulating layer on the single crystalline thin film, the first gate insulting layer having a substantially uniform thickness;
forming a first gate electrode on the first gate insulating layer to fill up the groove;
forming a recess in the isolation layer, the recess exposing the first and second sacrificial single crystalline layers;
removing the first and second sacrificial single crystalline layers from the recess;
performing a wet etching process on the isolation layer to enlarge a space formed by removing the first and second sacrificial single crystalline layers;
forming an ONO layer on an inner face of the space, the ONO layer having a substantially uniform thickness; and
forming a second gate electrode on ONO layer to fill up the space.

16. The method of claim 15, wherein the first and second single crystalline layers are doped with a first impurity.

17. The method of claim 16, wherein the single crystalline thin film is doped with a second impurity having an opposite polarity to the first impurity.

18. The method of claim 15, wherein a surface portion of the substrate is used as the first single crystalline layer and the upper sacrificial single crystalline layer, the single crystalline interlayer, the upper single crystalline layer, the second single crystalline layer and the single crystalline thin film are formed by an epitaxial growth process.

19. The method of claim 15, further comprising:
forming an insulating layer on the single crystalline thin film before the first gate insulating layer is formed, the insulating layer extending horizontally along the first single crystalline layer.

20. The method of claim 19, wherein forming the insulating layer comprises:
forming a preliminary insulating layer on the single crystalline thin film by depositing an insulating material to fill up the groove and then etching the insulating material.

21. The method of claim 15, including exposing the first single crystalline layer from a bottom face of the groove, wherein a pair of first source/drain regions are connected to each other.

22. The method of claim 15, further comprising exposing the substrate from a bottom face of the groove, wherein a pair of first source/drain regions are spaced apart from each other.
